(19) United States
(12) Patent Application Publication
(10) Pub. No.: US 2026/0068478 A1
(43) Pub. Date: Mar. 5, 2026

(54) DISPLAY DEVICE

(71) Applicant: LG Display Co., Ltd., Seoul (KR)

(72) Inventors: Jaeheon YUN, Paju-si (KR); JaeYoung OH, Paju-si (KR); Jinyoung LEE, Paju-si (KR)

(73) Assignee: LG Display Co., Ltd., Seoul (KR)

(21) Appl. No.: 19/264,646

(22) Filed: Jul. 9, 2025

(30) Foreign Application Priority Data
Aug. 29, 2024 (KR) 10-2024-0116379

(51) Int. Cl. H10K 59/65; H10K 59/131; H10K 59/40; H10K 59/80

(52) U.S. Cl. CPC H10K 59/65; H10K 59/131; H10K 59/40; H10K 59/80521; H10K 59/873; H10K 59/8792

(57) ABSTRACT

A display device according to an embodiment of the present specification includes a substrate including a display area, an optical area surrounded by the display area and including a through-hole, and a non-display area configured to surround the display area. A dam is disposed in the optical area on the substrate and configured to surround the through-hole. A plurality of anti-connection parts disposed in the optical area on the substrate and disposed closer to the through-hole than the dam. A metal pattern is disposed on the plurality of anti-connection parts and disposed between the plurality of anti-connection parts. This structure reduces surface level differences in the optical area, suppresses refraction of a polarizing layer, and improves visibility. Therefore, it is possible to improve visibility of the optical area.

### CROSS-REFERENCE TO RELATED APPLICATIONS

This application claims the priority of Korean Patent Application No. 10-2024-0116379 filed on Aug. 29, 2024, in the Korean Intellectual Property Office, the disclosure of which is incorporated herein by reference.

### BACKGROUND

### Technical Field

The present specification relates to a display device, and more particularly, to a display device capable of improving visibility in an area in which a through-hole is disposed.

### Description of the Related Art

Display devices, which visually display electrical information signals, are being rapidly developed in accordance with the entry into the information era. Various studies are being continuously conducted to develop a variety of display devices which are thin and lightweight, consume low power, and have improved performance.

As the representative display devices, there may be a liquid crystal display device (LCD), a field emission display device (FED), an electrowetting display device (EWD), an organic light-emitting display device (OLED), and the like.

An electroluminescent display device, as the representative organic light-emitting display device, refers to a display device that autonomously emits light. Unlike a liquid crystal display device, the electroluminescent display device does not require a separate light source and thus may be manufactured as a lightweight, thin display device. In addition, the electroluminescent display device is advantageous in terms of power consumption because the electroluminescent display device operates at a low voltage. Further, the electroluminescent display device is expected to be adopted in various fields because the electroluminescent display device is also excellent in implementation of colors, response speeds, viewing angles, and contrast ratios (CRs).

### BRIEF SUMMARY

The display device includes a specialized structure in the area surrounding a through-hole to improve image quality, visibility, and environmental resistance. A dam and multiple anti-connection parts are arranged concentrically around the through-hole to block the ingress of moisture and oxygen, thereby protecting the light-emitting elements. The anti-connection parts have a two-layer structure with an undercut profile that interrupts the continuity of the light-emitting layer, forming an effective barrier against external contaminants.

To reduce surface irregularities that can lead to refraction and visual distortion, the device incorporates metal patterns either positioned between or extending over the anti-connection parts. These metal patterns are formed on the same layer as the touch electrodes and help to planarize the upper surface of the optical area, improving display clarity. The metal patterns are further concealed beneath a black matrix to prevent visual detection, supporting both the functional and visual performance of the display while maintaining efficient fabrication.

For example, various embodiments of the present specification provide a display device capable of improving visibility in an area in which a through-hole is disposed.

Various embodiments of the present specification provide a display device capable of improving image quality by reducing light blurring in an area in which a through-hole is disposed.

Various embodiments of the present specification is to provide a display device capable of suppressing moisture permeation from the outside through a through-hole, thereby suppressing damage to a light-emitting element.

Technical benefits of the present disclosure are not limited to the above-mentioned benefits, and other benefits, which are not mentioned above, can be clearly understood by those skilled in the art from the following descriptions.

A display device according to an embodiment of the present specification includes a substrate including a display area, an optical area surrounded by the display area and including a through-hole, and a non-display area configured to surround the display area, a dam disposed in the optical area on the substrate and configured to surround the through-hole, a plurality of anti-connection parts disposed in the optical area on the substrate and disposed to be closer to the through-hole than the dam, and a metal pattern disposed on the plurality of anti-connection parts and disposed between the plurality of anti-connection parts.

A display device another embodiment of the present specification includes: a substrate including a display area, an optical area surrounded by the display area and including a through-hole, and a non-display area configured to surround the display area; a plurality of light-emitting elements disposed in the display area on the substrate and each including an anode, a light-emitting layer, and a cathode; an encapsulation part disposed on the plurality of light-emitting elements and including a first inorganic encapsulation layer, an organic encapsulation layer disposed on the first inorganic encapsulation layer, and a second inorganic encapsulation layer disposed on the organic encapsulation layer; a touch sensing part disposed on the encapsulation part and including a touch buffer layer, a plurality of touch connection electrodes disposed on the touch buffer layer, a touch interlayer insulation layer disposed on the plurality of touch connection electrodes, and a plurality of touch electrodes disposed on the touch interlayer insulation layer; a dam configured to surround the through-hole in the optical area on the substrate and define a concentric circle together with the through-hole; a plurality of anti-connection parts disposed to be closer to the through-hole than the dam in the optical area on the substrate and configured to define a concentric circle together with the through-hole; and a metal pattern disposed on the plurality of anti-connection parts, disposed between the plurality of anti-connection parts, and configured to define a concentric circle together with the through-hole.

Other detailed matters of the exemplary embodiments are included in the detailed description and the drawings.

According to the present specification, the metal pattern is disposed between the plurality of anti-connection parts in the optical area in which the through-hole is disposed, such that the top surfaces of the plurality of anti-connection parts may be planarized.

According to the present specification, the occurrence of refraction of the polarizing plate disposed on the top surfaces of the plurality of anti-connection parts in the optical area may be suppressed, such that the visibility of the display device may be improved.

According to the present specification, the occurrence of refraction of the polarizing plate disposed on the top surfaces of the plurality of anti-connection parts in the optical area may be suppressed, such that light blurring caused by the refraction of the polarizing plate may be suppressed, and the image quality of the display device may be improved.

According to the present specification, the light-emitting layers and the cathodes of the plurality of light-emitting elements may be separated by the plurality of anti-connection parts in the optical area, such that a transmission path for permeated moisture is disconnected even though moisture permeates from the through-hole, and the degradation of the plurality of light-emitting elements caused by the permeated moisture may be suppressed.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a block diagram for explaining a display device according to an embodiment of the present specification;

FIG. 2 is a view schematically illustrating a circuit configuration of a subpixel according to the embodiment of the present specification;

FIG. 3 is a top plan view of the display device according to the embodiment of the present specification;

FIG. 4 is a cross-sectional view taken along line IV-IV′ in FIG. 3;

FIG. 5 is an enlarged top plan view of area A in FIG. 3;

FIG. 6 is a cross-sectional view taken along line VI-VI′ in FIG. 5;

FIG. 7 is a top plan view of a display device according to another embodiment of the present specification; and

FIG. 8 is a cross-sectional view taken along line VIII-VIII′ in FIG. 7.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

The features of various embodiments of the present disclosure can be partially or entirely adhered to or combined with each other and can be interlocked and operated in technically various ways, and the embodiments can be carried out independently of or in association with each other.

Hereinafter, various exemplary embodiments of the present disclosure will be described in detail with reference to the accompanying drawings.

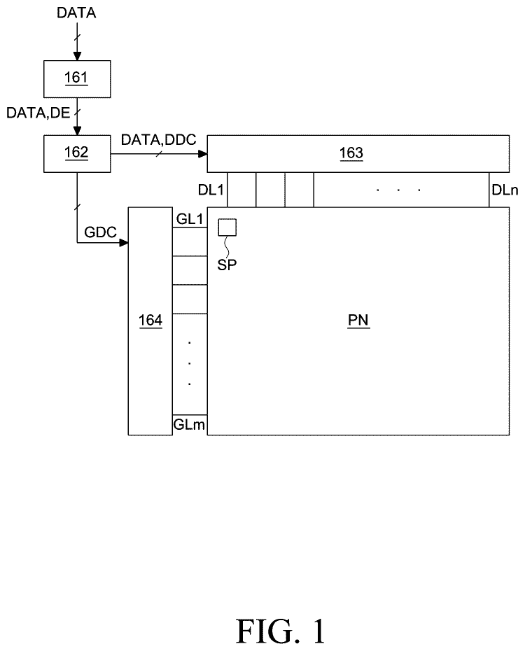

FIG. 1 is a block diagram of a display device according to an embodiment of the present specification.

With reference to FIG. 1, a display device of embodiments of the present disclosure may include an image processor 161, a timing controller 162, a data driver 163, a scan driver 164, and a display panel PN.

The image processor 161 may output a data signal DATA, a data enable signal DE, and the like supplied from the outside.

In addition, for example, the image processor 161 may output one or more of a vertical synchronizing signal, a horizontal synchronizing signal, and a clock signal in addition to the data enable signal DE.

The timing controller 162 may receive the data signal DATA in addition to the data enable signal DE or the driving signals including the vertical synchronizing signal, the horizontal synchronizing signal, and the clock signal from the image processor 161. In addition, on the basis of the driving signal, the timing controller 162 may output a gate timing control signal GDC for controlling an operation timing of the scan driver 164 and output a data timing control signal DDC for controlling an operation timing of the data driver 163.

In response to the data timing control signal DDC supplied from the timing controller 162, the data driver 163 may sample and latch the data signal DATA supplied from the timing controller 162, convert the data signal DATA into a gamma reference voltage, and output the gamma reference voltage. The data driver 163 may output the data signal DATA through data lines DLI to DLn. The data driver 163 may be provided in the form of an integrated circuit (IC).

In addition, the scan driver 164 may output the scan signal in response to the gate timing control signal GDC supplied from the timing controller 162. The scan driver 164 may output the scan signal through gate lines GL1 to GLm. The scan driver 164 may be provided in the form of an integrated circuit (IC) or formed on the display panel PN in a gate-in-panel (GIP) manner.

The display panel PN may display an image in response to the data signal DATA and the scan signal supplied from the data driver 163 and the scan driver 164.

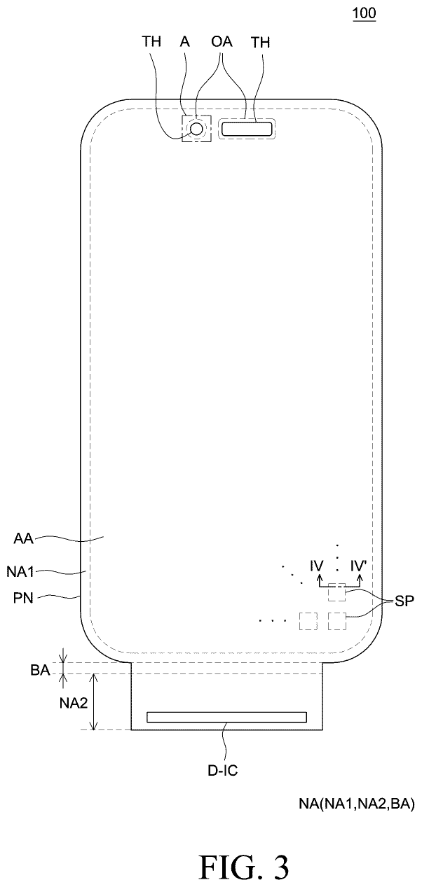

The display panel PN may include subpixels SP configured to display images. The display panel PN will be described in detail with reference to FIG. 3 to be described below.

For example, the subpixels SP may include a red subpixel, a green subpixel, and a blue subpixel or include a white subpixel, a red subpixel, a green subpixel, and a blue subpixel. The subpixel SP may have one or more different light-emitting areas depending on luminous properties.

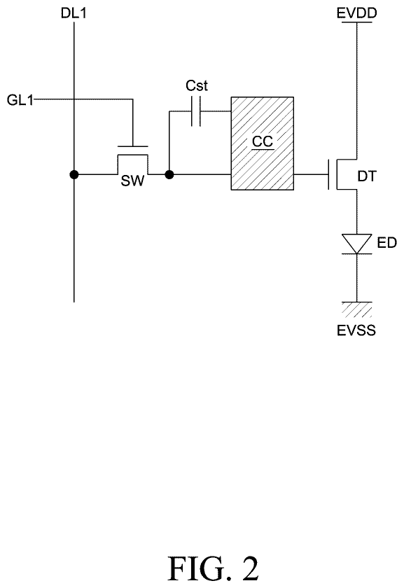

FIG. 2 is a view schematically illustrating a circuit configuration of the subpixel according to the embodiments of the present disclosure.

With reference to FIG. 2, one subpixel may include a switching transistor SW, a driving transistor DT, a capacitor Cst, a compensating circuit CC, and an organic light-emitting element ED.

For example, the switching transistor SW may perform a switching operation so that a data signal supplied through a first data line DLI is stored, as a data voltage, in the capacitor Cst in response to a scan signal supplied through a first gate line GL1. In addition, for example, the driving transistor DT may operate such that a drive current flows between a first power line EVDD (high-potential voltage) and a second power line EVSS (low-potential voltage) in accordance with the data voltage stored in the capacitor Cst. In addition, the organic light-emitting element ED may operate to emit light in accordance with a drive current produced by the driving transistor DT.

The compensating circuit CC refers to a circuit added into the subpixel to compensate for a threshold voltage of the driving transistor DT or the like. The compensating circuit CC may include one or more transistors. The compensating circuit CC may have very various configurations depending on an external compensation method.

The subpixel illustrated in FIG. 2 has a 2T (Transistor) 1C (Capacitor) structure including the switching transistor ST, the driving transistor DT, the capacitor Cst, and the light-emitting element ED. However, in case that the compensating circuit 135 is added, the subpixel may have various configurations such as 3T1C, 4T2C, 5T2C, 6T1C, 6T2C, 7T1C, 7T2C, or the like.

FIG. 3 is a top plan view of the display device according to the embodiment of the present specification. For convenience of description, FIG. 3 illustrates only the display panel PN and a data driver D-IC among various constituent elements of the display device 100.

The display panel PN may include a display area AA, optical areas OA surrounded by the display area AA and including through-holes TH, and a non-display area NA configured to surround the display area AA.

The display area AA is an area of the display panel PN in which images are displayed.

The plurality of subpixels SP and a circuit for operating the plurality of subpixels SP may be disposed in the display area AA. The plurality of subpixels SP may be minimum units that constitute the display area AA. Display elements may be respectively disposed in the plurality of subpixels SP. For example, an organic light-emitting element including an anode, a light-emitting layer, and a cathode may be disposed in each of the plurality of subpixels SP. However, the present specification is not limited thereto. In addition, the circuit configured to operate the plurality of subpixels SP may include driving elements, lines, and the like. For example, the circuit may include a thin-film transistor, a storage capacitor, a gate line, a data line, and the like. However, the present specification is not limited thereto.

The optical area OA is an area disposed in the display area AA, surrounded by the display area AA, and having the through-hole TH. The through-hole TH may be disposed in the display area AA of the display panel PN, thereby reducing a bezel area, which is the non-display area NA, and maximizing the display area AA. A design product with the maximized display area AA maximizes a degree of screen immersion of a user, thereby improving an aesthetic appearance.

The through-hole TH may be formed to correspond to an electronic optical device. The electronic optical device may be a device that receives light having passed through the display panel PN and performs a predetermined function in response to the received light. Therefore, the electronic optical device may be disposed to overlap the through-hole TH of the display panel PN. For example, the electronic optical device may be configured as a camera or various sensors. However, the present specification is not limited thereto. The electronic optical device may include all devices that perform predetermined functions in response to the light. Meanwhile, because the electronic optical device is disposed below the display panel PN, the electronic optical device may not be visually recognized by the user. For example, in case that the electronic optical device is a camera, the camera is disposed on the rear surface of the display panel PN. However, the camera may capture an image of the front surface of the display device 100 instead of the rear surface of the display device 100.

FIG. 3 illustrates two through-holes TH. However, the present specification is not limited thereto. The number of through-holes TH may be variously provided. For example, one or two through-holes are disposed in the display area AA. A camera may be disposed in a first hole, and a distance sensing sensor, a face recognition sensor, or a wide angle camera may be disposed in a second hole.

The non-display area NA is an area in which no image is displayed. Various lines, various circuits, and the like for operating the display elements in the display area AA are disposed in the non-display area NA. For example, the non-display area NA may include link lines for transmitting signals to the plurality of subpixels and the circuit in the display area AA. The non-display area NA may include gate-in-panel (GIP) lines or drive ICs such as the gate driver and the data driver.

The non-display area NA may be an area extending from the display area AA. However, the present specification is not limited thereto. The non-display area NA may be an area that surrounds the display area AA.

The non-display area NA includes a first non-display area NA1, a bending area BA, and a second non-display area NA2. The first non-display area NA1 is an area extending from the display area AA while surrounding the display area AA. The bending area BA may be an area extending from one side of the first non-display area NA1 and bent. The second non-display area NA2 may be an area extending from the bending area BA and disposed below the display area.

The first non-display area NA1 and the second non-display area NA2 may be areas disposed on the same plane as the display area AA or disposed in parallel with the display area AA and kept in a flat state. For example, the first non-display area NA1 may be disposed flat on the same plane as the display area AA, and the second non-display area NA2 may be disposed flat below the display area AA and disposed in parallel with the display area AA. Therefore, for example, the display area AA, the first non-display area NA1, and the second non-display area NA2 may be referred to as non-bending areas. However, the present specification is not limited thereto.

The drive IC D-IC may be disposed in the second non-display area NA2. The drive IC D-IC may be a data driver configured to provide the data signal to the plurality of subpixels SP. For example, a pad part may be disposed in the second non-display area NA2 in which the drive IC D-IC is disposed, and a printed circuit board electrically connected to the pad part may be further disposed and provide a signal to the drive IC D-IC. However, the present specification is not limited thereto.

Meanwhile, the drive IC D-IC may be disposed in the form of a chip-on panel (COP) at one side of the display panel PN and connected to the display panel PN. Alternatively, the drive IC D-IC may be provided in the form of a chip-on film (COF) disposed on a separate flexible film and connected to the display panel PN. However, the present specification is not limited thereto.

As the display panel PN is bent, the drive IC D-IC disposed in the second non-display area NA2 is disposed below the display area AA. For example, the drive IC D-IC and the printed circuit board, which is connected to the pad part of the display panel PN, may move to a rear surface side of the display panel PN and overlap the display area AA. Therefore, the circuit elements, such as the drive IC D-IC and the printed circuit board, may not be visually recognized when viewed from above the display panel PN. Therefore, a size of the non-display area NA, which is visually recognized from above the display panel PN, may be reduced, such that a narrow bezel may be implemented.

The display device 100 may further include various additional elements configured to generate various signals or operate a pixel in the display area AA. The additional elements for operating the pixel may include an inverter circuit, a multiplexer, an electrostatic discharge (ESD) circuit, and the like. The display device 100 may also include additional elements related to functions other than the function of operating the pixel. For example, the display device 100 may further include additional elements that provide a touch sensing function, a user certification function (e.g., fingerprint recognition), a multi-level pressure sensing function, a tactile feedback function, and the like. The above-mentioned additional elements may be positioned in the non-display area NA and/or an external circuit connected to a connection interface.

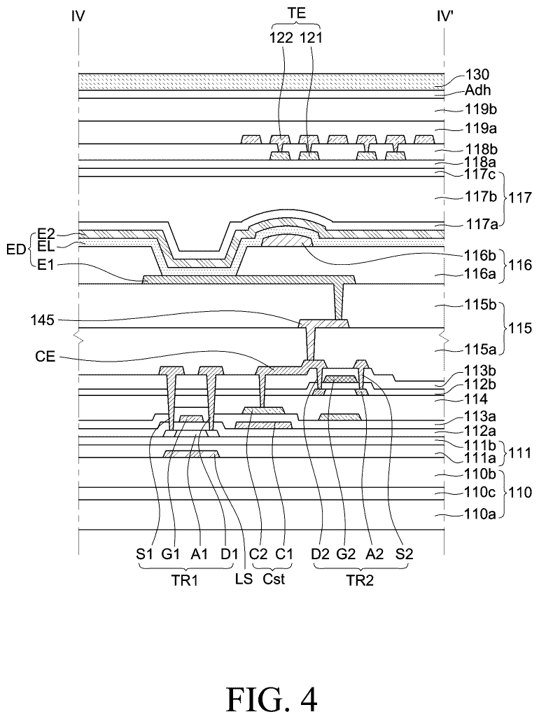

Hereinafter, a cross-sectional structure of the display device 100 will be described in more detail with reference to FIG. 4.

FIG. 4 is a cross-sectional view taken along line IV-IV′ in FIG. 3.

With reference to FIGS. 3 and 4 together, the display device 100 according to the embodiment of the present specification may include the display panel PN, a bonding layer Adh, and a polarizing layer 130.

The display panel PN may include a substrate 110, a first buffer layer 111, a first thin-film transistor TR1, a second thin-film transistor TR2, a first gate insulation layer 112a, a first interlayer insulation layer 113a, a second buffer layer 114, a second gate insulation layer 112b, a second interlayer insulation layer 113b, a connection electrode CE, a first planarization layer 115a, a second planarization layer 115b, an auxiliary electrode 145, a bank 116a, a spacer 116b, an anode E1, a light-emitting layer EL, a cathode E2, an encapsulation part 117, a touch electrode TE, a first organic layer 119a, and a second organic layer 119b.

The substrate 110 serves to support and protect the components of the flexible display device that are disposed above the substrate 110.

The substrate 110 is a component for supporting various constituent elements included in the display device 100 and may be made of an insulating material. The substrate 110 may include a first substrate 110a, a second substrate 110b, and an interlayer insulation film 110c. The interlayer insulation film 110c may be disposed between the first substrate 110a and the second substrate 110b. As described above, the substrate 110 is configured by the first substrate 110a, the second substrate 110b, and the interlayer insulation film 110c, which may suppress moisture permeation. For example, the first substrate 110a and the second substrate 110b may each be a polyimide (PI) substrate, and the interlayer insulation film 110c may be configured as a single layer made of silicon nitride (SiNx) or silicon oxide (SiOx) or a multilayer including the above-mentioned layers.

A light-blocking layer LS may be disposed on the substrate 110.

The first buffer layer 111 may be disposed on the substrate 110 while covering the light-blocking layer LS. Specifically, a multi-buffer layer 111a may be disposed on the substrate 110 while covering the light-blocking layer LS, and an active buffer layer 111b may be disposed on the multi-buffer layer 111a.

The multi-buffer layer 111a may delay diffusion of moisture or oxygen having permeated into the substrate 110 and include at least any one of silicon nitride (SiNx) and silicon oxide (SiOx).

The active buffer layer 111b may protect a first active layer A1 and suppress various types of defects introduced from the substrate 110. For example, the active buffer layer 111b may include at least any one of a-Si, silicon nitride (SiNx), and silicon oxide (SiOx).

The first thin-film transistor TR1 may be disposed on the first buffer layer 111. The first thin-film transistor TR1 may include the first active layer A1, a first gate electrode G1, a first source electrode S1, and a first drain electrode D1. In this case, in accordance with design of a pixel circuit, the first source electrode D1 may be a first drain electrode, and the first drain electrode D1 may be a first source electrode.

The first active layer A1 may be disposed on the first buffer layer 111 so as to overlap the light-blocking layer LS. The first active layer A1 may include amorphous silicon or polysilicon (polycrystalline silicon). For example, the first active layer A1 may include low-temperature polysilicon (LTPS). For example, because a polysilicon material has high mobility (100 cm²/Vs or more), low energy power consumption, and excellent reliability, the polysilicon material may be applied to gate drivers and/or multiplexers (MUX) for driving elements for operating thin-film transistors for display elements. In the display device 100 according to the embodiment of the present specification, the polysilicon material may be applied to an active layer A1 of the thin-film driving transistor. However, the present specification is not limited thereto. For example, the polysilicon material may also be applied to an active layer A2 of the switching thin-film transistor in accordance with the properties of the display device 100. The first active layer A1 may be formed by depositing an amorphous silicon (a-Si) material on the first buffer layer 111, forming polysilicon by performing a dehydration process and a crystallization process, and then patterning the polysilicon. In this case, the first active layer A1 may include a first channel area in which a channel is formed when the first thin-film transistor TR1 operates, and a first source area and a first drain area disposed at two opposite sides of the first channel area. The first source area means a portion of the first active layer A1 connected to the first source electrode S1, and the first drain area means a portion of the first active layer A1 connected to the first drain electrode D1. For example, the first source area and the first drain area may be configured by doping the first active layer A1 with ions (impurities). The first source area and the first drain area may be formed by doping the polysilicon material with ions. The first channel area may mean a portion in which the polysilicon material remains without being subjected to the ion doping.

The first gate insulation layer 112a may be disposed on the first active layer A1. The first gate insulation layer 112a may be configured as a single layer made of silicon nitride (SiNx) or silicon oxide (SiOx) or a multilayer including the above-mentioned layers. The first gate insulation layer 112a may have contact holes through which the first source electrode S1 and the first drain electrode D1 of the first thin-film transistor TR1 are respectively connected to the first source area and the first drain area of the first active layer A1 of the first thin-film transistor TR1.

The first gate electrode G1 of the first thin-film transistor TR1 and a first capacitor electrode C1 of a storage capacitor Cst may be disposed on the first gate insulation layer 112a.

In this case, the first gate electrode G1, a gate metal GM, and the first capacitor electrode C1 may each be configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. The first gate electrode G1 may be formed on the first gate insulation layer 112a so as to overlap the first channel area of the first active layer A1 of the first thin-film transistor TR1.

The first capacitor electrode C1 may be excluded on the basis of the operating properties of the display device 100 and the structure, type, and the like of the thin-film transistor. The first gate electrode G1 and the first capacitor electrode C1 may be formed by the same process. Further, the first gate electrode G1 and the first capacitor electrode C1 may be made of the same material and formed on the same layer.

The first interlayer insulation layer 113a may be disposed above the first gate insulation layer 112a, the first gate electrode G1, and the first capacitor electrode C1. The first interlayer insulation layer 113a may be configured as a single layer made of silicon nitride (SiNx) or silicon oxide (SiOx) or a multilayer including the above-mentioned layers. Further, the first interlayer insulation layer 113a may have a contact hole through which the first source area and the first drain area of the first active layer A1 of the first thin-film transistor TR1 are exposed.

A second capacitor electrode C2 of the storage capacitor Cst may be disposed on the first interlayer insulation layer 113a. The second capacitor electrode C2 may be configured as a single layer or multilayer made of any one of molybdenum (Mo), copper (Cu), titanium (Ti), aluminum (Al), chromium (Cr), gold (Au), nickel (Ni), neodymium (Nd), and an alloy thereof. The second capacitor electrode C2 may be formed on the first interlayer insulation layer 113a so as to overlap the first capacitor electrode C1. In addition, the second capacitor electrode C2 may be made of the same material as the first capacitor electrode C1. The second capacitor electrode C2 may be excluded on the basis of the operating properties of the display device 100 and the structure, type, and the like of the thin-film transistor.

The second buffer layer 114 may be disposed on the first interlayer insulation layer 113a and the second capacitor electrode C2. The second buffer layer 114 may be configured as a single layer made of silicon nitride (SiNx) or silicon oxide (SiOx) or a multilayer including the above-mentioned layers. The second buffer layer 114 may have a contact hole through which the first source area and the first drain area of the first active layer A1 of the first thin-film transistor TR1 are exposed. In addition, the second buffer layer 114 may have a contact hole through which the second capacitor electrode C2 of the storage capacitor Cst is exposed.

The second buffer layer 114 may be configured as a multilayer. However, the present specification is not limited thereto.

A second active layer A2 of the second thin-film transistor TR2 may be disposed on the second buffer layer 114. In this case, the second thin-film transistor TR2 may include the second active layer A2, the second gate insulation layer 112b, a second gate electrode G2, a second source electrode S2, and a second drain electrode D2. In this case, in accordance with design of the pixel circuit, the second source electrode S2 may be a drain electrode, and the second drain electrode D2 may be a source electrode.

In addition, the second active layer A2 may include a second channel area in which a channel is formed when the second thin-film transistor TR2 operates, and a second source area and a second drain area disposed at two opposite sides of the second channel area. The second source area may mean a portion of the second active layer A2 connected to the second source electrode S2, and the second drain area may mean a portion of the second active layer A2 connected to the second drain electrode D2.

The second active layer A2 may be made of an oxide semiconductor. The oxide semiconductor material is a material having a larger band gap than a silicon material and has a low off-current because electrons cannot pass through the band gap in an OFF state. Therefore, the thin-film transistor including the active layer made of the oxide semiconductor may be suitable for a switching thin-film transistor that maintains the short ON time and the long OFF time. However, the present specification is not limited thereto. The oxide semiconductor may also be applied to the thin-film driving transistor in accordance with the properties of the display device 100. Further, because the oxide semiconductor material has a low off-current and may decrease a magnitude of an auxiliary capacity, the oxide semiconductor material is suitable for a high-resolution display element. For example, the second active layer A2 may be made of a metal oxide, for example, various metal oxides such as indium-gallium-zinc oxide (IGZO). In this case, the description has been made on the assumption that the second active layer A2 of the second thin-film transistor TR2 is made of IGZO among various metal oxides. However, the present specification is not limited thereto. The second active layer A2 of the second thin-film transistor TR2 may be made of another metal oxide, such as indium-zinc oxide (IZO), indium-gallium-tin oxide (IGTO), or indium-gallium oxide (IGO), instead of IGZO.

The second active layer A2 may be formed by depositing a metal oxide on the second buffer layer 114, performing a heat treatment process for stabilization, and then patterning the metal oxide.

The second gate insulation layer 112b may be disposed on the entire substrate 110 including the second active layer A2. For example, the second gate insulation layer 112b may be configured as a single layer made of silicon nitride (SiNx) or silicon oxide (SiOx) or a multilayer including the above-mentioned layers.

The second gate electrode G2 may be disposed on the second gate insulation layer 112b.

The second gate electrode G2 may be configured as a single layer or multilayer made of any one of molybdenum (Mo), copper (Cu), titanium (Ti), aluminum (Al), chromium (Cr), gold (Au), nickel (Ni), neodymium (Nd), and an alloy thereof.

For example, the second gate electrode G2 is formed by forming a metallic material on the second gate insulation layer 112b, forming a photoresist pattern on the metallic material, and then wet-etching the metallic material by using the photoresist pattern as a mask. A material, which selectively etches molybdenum (Mo), copper (Cu), titanium (Ti), aluminum (Al), chromium (Cr), gold (Au), nickel (Ni), and neodymium (Nd), or an alloy thereof, which constitutes the metallic material and does not etch the insulating material, may be used as a wet etching liquid for etching the metallic material.

The second interlayer insulation layer 113b may be disposed on the second gate insulation layer 112b and the second gate electrode G2. The second interlayer insulation layer 113b may have a contact hole through which the first active layer A1 of the first thin-film transistor TR1 and the second active layer A2 of the second thin-film transistor TR2 are exposed. For example, the second interlayer insulation layer 113b may have a contact hole through which the first source area and the first drain area of the first active layer A1 of the first thin-film transistor TR1 are exposed. The second interlayer insulation layer 113b may have a contact hole through which the second source area and the second drain area of the second active layer A2 of the second thin-film transistor TR2 are exposed.

The second interlayer insulation layer 113b may be configured as a single layer made of silicon nitride (SiNx) or silicon oxide (SiOx) or a multilayer including the above-mentioned layers.

The connection electrode CE, the first source electrode S1 and the second drain electrode D1 of the first thin-film transistor TR1, and the second source electrode S2 and the second drain electrode D2 of the second thin-film transistor TR2 may be disposed on the second interlayer insulation layer 113b.

The connection electrode CE may be electrically connected to the second drain electrode D2 of the second thin-film transistor TR2. Further, the connection electrode CE may be electrically connected to the second capacitor electrode C2 of the storage capacitor Cst through contact holes formed in the second buffer layer 114 and the second interlayer insulation layer 113b. That is, the connection electrode CE may serve to electrically connect the second capacitor electrode C2 of the storage capacitor Cst and the second drain electrode D2 of the second thin-film transistor TR2.

In this case, the first source electrode S1 and the first drain electrode D1 of the first thin-film transistor TR1 may be connected to the first active layer A1 of the first thin-film transistor TR1 through contact holes formed in the first gate insulation layer 112a, the first interlayer insulation layer 113a, the second buffer layer 114, and the second interlayer insulation layer 113b.

The second source electrode S2 and the second drain electrode D2 of the second thin-film transistor TR2 may be connected to the second active layer A2 through a contact hole formed in the second interlayer insulation layer 112b.

The connection electrode CE, the first source electrode S1 and the first drain electrode D1 of the first thin-film transistor TR1, and the second source electrode S2 and the second drain electrode D2 of the second thin-film transistor TR2 may be formed by the same process and made of the same material.

For example, the connection electrode CE, the first source electrode S1 and the first drain electrode D1 of the first thin-film transistor TR1, and the second source electrode S2 and the second drain electrode D2 of the second thin-film transistor TR2 may each configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. For example, the connection electrode CE, the first source electrode S1 and the first drain electrode D1 of the first thin-film transistor TR1, and the second source electrode S2 and the second drain electrode D2 of the second thin-film transistor TR2 may each have a three-layer structure including titanium (Ti)/aluminum (Al)/titanium (Ti). However, the present specification is not limited thereto.

The connection electrode CE may be integrally connected to the second drain electrode D2 of the second thin-film transistor TR2. However, the present specification is not limited thereto.

The first planarization layer 115a may be disposed above the connection electrode CE, the first source electrode S1 and the first drain electrode D1 of the first thin-film transistor TR1, the second source electrode S2 and the second drain electrode D2 of the second thin-film transistor TR2, and the second interlayer insulation layer 113b.

The first planarization layer 115a may be an organic layer for planarizing and protecting an upper portion of the first thin-film transistor TR1 and an upper portion of the second thin-film transistor TR2. For example, the first planarization layer 115a may be made of an organic material such as acrylic resin, epoxy resin, phenolic resin, polyamide resin, and polyimide resin.

The auxiliary electrode 145 may be disposed on the first planarization layer 115a. The auxiliary electrode 145 may be connected to the second drain electrode D2 of the second thin-film transistor TR2 through a contact hole of the first planarization layer 115a. The auxiliary electrode 145 may serve to electrically connect the second thin-film transistor TR2 and a first electrode E1. Further, the auxiliary electrode 145 may be configured as a single layer or multilayer made of any one of molybdenum (Mo), copper (Cu), titanium (Ti), aluminum (Al), chromium (Cr), gold (Au), nickel (Ni), neodymium (Nd), and an alloy thereof. The auxiliary electrode 145 may be made of the same material as the second source electrode S2 and the second drain electrode D2 of the second thin-film transistor TR2.

The second planarization layer 115b may be disposed above the auxiliary electrode 145 and the first planarization layer 115a. For example, the second planarization layer 115b may be made of an organic material such as acrylic resin, epoxy resin, phenolic resin, polyamide resin, and polyimide resin.

The light-emitting element ED may be disposed on the second planarization layer 115b.

The anode E1 may be disposed on the second planarization layer 115b. In this case, the anode E1 may be electrically connected to the auxiliary electrode 145 through a contact hole provided in the second planarization layer 115b. The anode E1 may be made of a metallic material.

In case that the display device 100 is a top-emission type display device in which light emitted from the light-emitting element ED propagates toward an upper side of the substrate SUB on which the light-emitting element ED is disposed, the anode E1 may further include a transparent conductive layer and a reflective layer disposed on the transparent conductive layer. For example, the transparent conductive layer may be made of transparent conductive oxide such as ITO or IZO. For example, the reflective layer may be made of silver (Ag), aluminum (Al), gold (Au), molybdenum (Mo), tungsten (W), chromium (Cr), or an alloy thereof.

The bank 116a may be disposed to cover the anode E1. A portion of the bank 116a, which corresponds to the light-emitting area of the subpixel, may be opened. A part of the anode E1 may be exposed through the opened portion (hereinafter, referred to as an open area) of the bank 116a. In this case, the bank 116a may be made of an inorganic insulating material such as silicon nitride (SiNx) or silicon oxide (SiOx), or an organic insulating material such as benzocyclobutene-based resin, acrylic resin, or imide-based resin. However, the present specification is not limited thereto. The spacer 116b may be further disposed on the bank 116a.

The light-emitting layer EL may be disposed in the open area of the bank 116a and an area at the periphery of the open area. Therefore, the light-emitting layer EL may be disposed on the anode E1 exposed through the open area of the bank 116a.

The light-emitting layer EL may include a plurality of organic films. For example, the light-emitting layer EL serves to emit light. The light-emitting layer EL may include a hole injection layer (HIL), a hole transport layer (HTL), a light-emitting layer, an electron transport layer (ETL), and an electron injection layer (EIL). However, some components may be excluded depending on the structure or properties of the display device. In this case, an electroluminescent layer and an inorganic light-emitting layer may be applied as the light-emitting layer EL.

The hole injection layer is disposed on the anode E1 and serves to facilitate the injection of the positive holes.

The hole transport layer is disposed on the hole injection layer and serves to smoothly transmit the positive holes to the light-emitting layer.

The light-emitting layer is disposed on the hole transport layer. The light-emitting layer may be made of a material capable of emitting light with a particular color, thereby emitting the light with the particular color. For example, a phosphorescent material or a fluorescent material may be used as the light-emitting material.

The electron injection layer may further be disposed on the electron transport layer. The electron injection layer is an organic layer that facilitates the injection of electrons from the cathode E2. The electron injection layer may be excluded depending on the structure and properties of the display device.

An electron blocking layer for blocking a flow of electrons or a hole blocking layer for blocking a flow of positive holes may be further disposed at a position adjacent to the light-emitting layer EL. Therefore, it is possible to inhibit the electron from moving from the light-emitting layer and passing through the adjacent hole transport layer when the electrons are injected into the light-emitting layer or inhibit the positive hole from moving from the light-emitting layer and passing through the adjacent electron transport layer when the positive holes are injected into the light-emitting layer, thereby improving luminous efficiency.

The cathode E2 may be disposed on the light-emitting layer EL. The cathode E2 serves to supply electrons to the light-emitting layer EL. The cathode E2 needs to supply electrons. Therefore, the cathode E2 may be made of a metallic material such as magnesium (Mg), a silver-magnesium alloy, or the like that is an electrically conductive material having a low work function. However, the present specification is not limited thereto. For example, in case that the display device 100 is a top-emission type display device, the cathode E2 may include transparent conductive oxide such as indium tin oxide (ITO), indium zinc oxide (IZO), indium-tin-zinc oxide (ITZO), zinc oxide (ZnO), and tin oxide (TO).

The light-emitting element ED may be formed by the anode E1, the light-emitting layer EL, and the cathode E2.

An encapsulation layer 117 may be positioned on the light-emitting element ED.

The encapsulation layer 117 may have a single-layer structure or a multilayer structure. For example, the encapsulation layer 117 may include a first encapsulation layer 117a, a second encapsulation layer 117b, and a third encapsulation layer 117c.

In this case, the first encapsulation layer 117a and the third encapsulation layer 117c may each be made of an inorganic film, and the second encapsulation layer 117b may be made of an organic film. Among the first encapsulation layer 117a, the second encapsulation layer 117b, and the third encapsulation layer 117c, the second encapsulation layer 117b may be thickest and serve as a planarization layer.

The first encapsulation layer 117a may be disposed on the cathode E2 and closest to the light-emitting element ED. The first encapsulation layer 117a may be made of an inorganic insulating material that may be deposited at a low temperature. For example, the first encapsulation layer 117a may be made of silicon nitride (SiNx), silicon oxide (SiOx), silicon oxynitride (SiON), aluminum oxide (Al₂O₃), or the like. Because the first encapsulation layer 117a is deposited in a low-temperature ambience, it is possible to suppress damage to the light-emitting layer EL made of an organic material vulnerable to a high-temperature ambience during a deposition process.

The second encapsulation layer 117b may have a smaller area than the first encapsulation layer 117a. In this case, the second encapsulation layer 117b may be formed to expose two opposite ends of the first encapsulation layer 117a. The second encapsulation layer 117b may serve as a buffer for mitigating stress between the layers caused when the flexible display device is bent. The second encapsulation layer 117b may serve to improve the planarization performance.

For example, the second encapsulation layer 117b may be made of an organic insulating material such as acrylic resin, epoxy resin, polyimide, polyethylene, or silicon oxycarbon (SiOC). For example, the second encapsulation layer 117b may also be formed in an inkjet manner. However, the present specification is not limited thereto.

The third encapsulation layer 117c may be formed above the substrate 110 having the second encapsulation layer 117b to cover a top surface and a side surface of each of the second encapsulation layer 117b and the first encapsulation layer 117a. In this case, the third encapsulation layer 117c may minimize or block the permeation of outside moisture or oxygen into the first encapsulation layer 117a and the second encapsulation layer 117b. For example, the third encapsulation layer 117c may be made of an inorganic insulating material such as silicon nitride (SiNx), silicon oxide (SiOx), silicon oxynitride (SiON), or aluminum oxide (Al₂O₃).

A touch sensing part may be disposed on the third encapsulation layer 117c. Specifically, the touch sensing part may include a touch buffer layer 118a disposed on the third encapsulation layer 117c, a plurality of touch connection electrodes 121 disposed on the touch buffer layer 118a, a touch interlayer insulation layer 118b disposed on the plurality of touch connection electrodes 121, a plurality of touch electrodes 122 disposed on the touch interlayer insulation layer 118b, the first organic layer 119a disposed to cover the plurality of touch electrodes 122, and the second organic layer 119b disposed on the first organic layer 119a.

The touch buffer layer 118a may inhibit outside moisture, foreign substances, or a liquid chemical such as a developer or an etching liquid, which is used during a process of manufacturing the touch electrodes TE formed on the touch buffer layer 118a, from permeating into the light-emitting element ED.

In order to suppress damage to the light-emitting layer EL including an organic material vulnerable to a high temperature, the touch buffer layer 118a may be made of an organic insulating material that may be formed at a predetermined low temperature (e.g., 100° C. or less) and have low permittivity of 1 to 3. For example, the touch buffer layer 118a may be made of an acrylic-based, epoxy-based, or siloxane-based material.

The touch buffer layer 118a may be formed to extend to the non-display area NA or the optical area OA as well as the display area AA.

The plurality of touch connection electrodes 121 are disposed on the touch buffer layer 118a. The plurality of touch connection electrodes 121 are disposed in the display area AA and electrically connect the plurality of touch electrodes 122 on the touch interlayer insulation layer 118b.

In this case, the contact hole may be formed through the touch interlayer insulation layer 118b. The plurality of touch connection electrodes 121 are disposed below the touch interlayer insulation layer 118b, and upper portions of the plurality of touch connection electrodes 121 are partially exposed by the contact holes.

For example, the plurality of touch connection electrodes 121 may each be configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. However, the present specification is not limited thereto. For example, the plurality of touch connection electrodes 121 may each have a three-layer structure made of titanium (Ti), aluminum (Al), and titanium (Ti).

The touch interlayer insulation layer 118b may be disposed on the touch buffer layer 118a to cover the plurality of touch connection electrodes 121 and insulate the plurality of touch connection electrodes 121 and the plurality of touch electrodes 122. The touch interlayer insulation layer 118b may be formed to extend to the non-display area NA or the optical area OA as well as the display area AA.

For example, the touch interlayer insulation layer 118b may be configured as a single layer or multilayer made of silicon nitride (SiNx) or silicon oxide (SiOx). However, the present specification is not limited thereto.

The plurality of touch electrodes 122 is disposed on the touch interlayer insulation layer 118b. The plurality of touch electrodes 122 are connected in a first direction to define a plurality of electrode columns and connected in a row direction by the plurality of touch connection electrodes 121 to define a plurality of electrode rows.

For example, the plurality of touch electrodes 122 may each be configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. However, the present specification is not limited thereto. For example, the plurality of touch electrodes 122 may each have a three-layer structure made of titanium (Ti), aluminum (Al), and titanium (Ti).

The first organic layer 119a may be disposed to cover the plurality of touch electrodes TE. For example, the first organic layer 119a may be made of an organic material such as acrylic resin, epoxy resin, phenolic resin, polyamide resin, and polyimide resin. The first organic layer 119a may suppress a level difference of the constituent elements of the display panel PN disposed below the first organic layer 119a, thereby improving the visibility of the display device. For example, the first organic layer 119a may also be referred to as a first touch planarization layer 119a.

In addition, the second organic layer 119b may be disposed above the first organic layer 119a. The second organic layer 119b made of an organic material is disposed on an uppermost layer of the display panel PN, thereby suppressing the occurrence of a crack in the uppermost layer of the display panel caused by an external force. In addition, the second organic layer 119b may suppress a level difference on the uppermost layer of the display panel PN, thereby further improving the visibility of the display device. For example, the second organic layer 119b may be made of the same material as the first organic layer 119a. However, the present specification is not limited thereto. For example, the second organic layer 119b may also be referred to as a second touch planarization layer 119b.

Meanwhile, the polarizing layer 130 may be disposed on the display panel PN.

The polarizing layer 130 suppresses reflection of external light in the display area AA of the substrate 110. In case that the display device 100 is used outside, external natural light may be introduced and reflected by the reflective layer included in the anode E1 of the light-emitting element ED or reflected by an electrode made of metal and disposed on a lower portion of the light-emitting element ED. The light beams, which are reflected as described above, may inhibit an image on the display device 100 from being visually recognized. The polarizing layer may polarize, in a particular direction, the light introduced from the outside, thereby inhibiting the reflected light from being discharged again to the outside of the display device 100.

The bonding layer Adh may be disposed between the second organic layer 119b and the polarizing layer 130. The bonding layer Adh may fix the second organic layer 119b and the polarizing layer 130. The bonding layer Adh may minimize the occurrence of foreign substances or bubbles between the second organic layer 119b and the polarizing layer 130, and an optically transparent bonding agent, such as an optically clear adhesive (OCA) or an optical clear resin (OCR), may be used. However, the present specification is not limited thereto.

Although not illustrated, a cover member may be bonded onto the polarizing layer by the bonding layer. The bonding layer may serve to bond the constituent elements of the display device 100. For example, the bonding layer may be formed by using a bonding agent for an optically transparent display such as a pressure-sensitive bonding agent, an optically transparent bonding agent (optical clear adhesive (OCR)), or an optically transparent resin (optical clear resin (OCR)). However, the present specification is not limited thereto.

The cover member may protect the constituent elements of the display device 100 from external impact and suppress damage such as scratches. For example, the cover member may be a tempered glass. However, the present specification is not limited thereto.

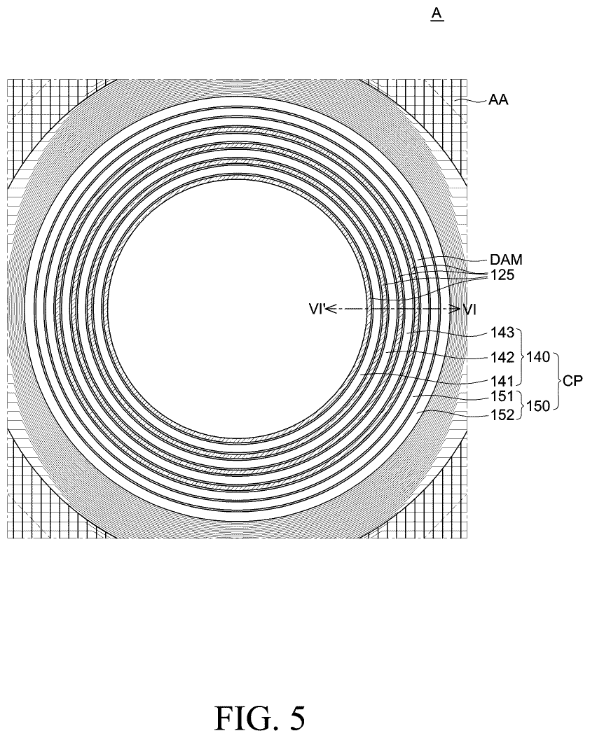

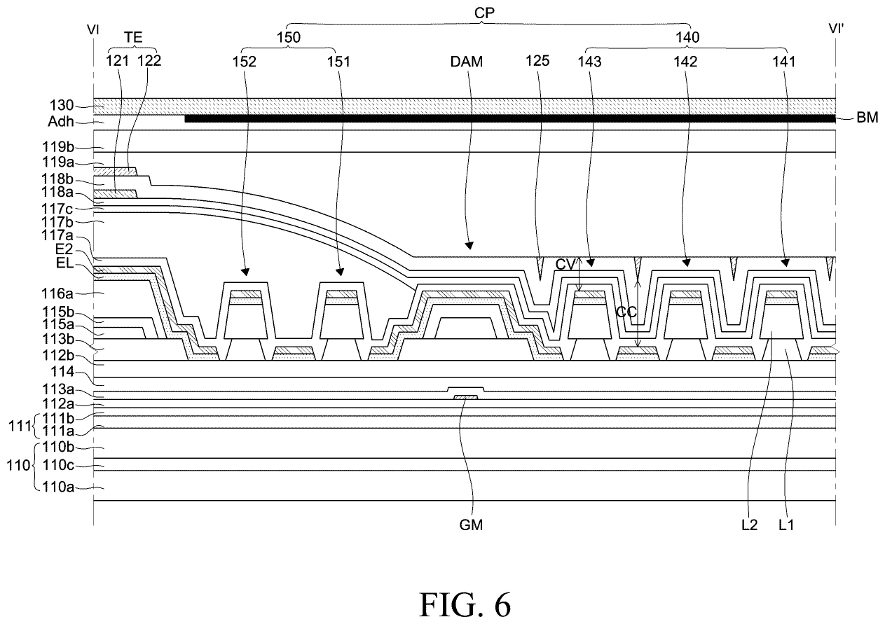

Hereinafter, a cross-sectional structure of the optical area OA will be described in more detail with reference to FIGS. 5 and 6.

FIG. 5 is an enlarged top plan view illustrating area A corresponding to the optical area in FIG. 3. FIG. 6 is a cross-sectional view taken along line VI-VI′ in FIG. 5. For convenience of description, FIG. 5 illustrates only a plurality of anti-connection parts CP, a dam DAM, and metal patterns 125 among various constituent elements of the display device.

The optical area OA may include an area in which the through-hole TH and the anti-connection part CP and the dam DAM, which surround the through-hole TH, are disposed.

With reference to FIGS. 5 and 6 together, the dam DAM may be disposed in the optical area OA and block a flow of the second encapsulation layer 117b that constitutes the encapsulation part 117. The dam DAM may be disposed in the form of a closed loop that surrounds the through-hole TH in the optical area OA. For example, the first encapsulation layer 117a and the third encapsulation layer 117c may be disposed on the dam DAM, and a flow of the second encapsulation layer 117b may be blocked by the dam DAM. The dam DAM needs to have a predetermined height or higher to block a flow of the second encapsulation layer 117b. To this end, the dam DAM needs to be configured by one or more layers at least made of an organic material. For example, the dam DAM may include a lower layer made of the same material as the second interlayer insulation layer 113b, a middle layer made of the same material as the second planarization layer 115b, and an upper layer made of the same material as the bank 116a. However, the present specification is not limited thereto. The drawings illustrate a configuration in which one dam DAM is provided. However, two or more dams DAM may be provided.

The gate metal GM may be disposed below the dam DAM and overlap the dam DAM. For example, the gate metal GM, which overlaps the dam DAM, may be disposed on the same layer and made of the same material as the first gate electrode G1. For example, the gate metal GM may be a mark indicating a position at which the through-hole TH is removed when the through-hole TH is removed by a laser in a step of completely manufacturing the display panel PN. For example, the mark may be spaced apart from the through-hole TH by several tens of micrometers to several hundred micrometers. However, the present specification is not limited thereto.

The light-emitting element ED and the pixel circuit in the corresponding area are removed to dispose the through-hole TH. However, the light-emitting elements ED and the pixel circuits disposed at upper, lower, left, and right sides based on the optical area OA need to be electrically connected. To this end, the high-potential power line, the gate line, and the like may be disposed in the non-display area NA adjacent to the optical area OA so as to be connected at the upper, lower, left, and right sides while bypassing the through-hole.

In the display device 100 according to the embodiment of the present specification, the anti-connection part CP and the dam DAM may be disposed in a closed loop shape that defines a concentric circle together with the through-hole TH based on the through-hole TH. That is, the dam DAM may be disposed in a circular arrangement concentric with the through-hole TH (or simply, arranged concentrically around the through-hole). Similarly, the anti-connection part CP may be disposed in a circular arrangement concentric with the through-hole TH. For example, if any one of the anti-connection part and the dam is cracked, there may occur a problem in that moisture and oxygen permeate into the display area from the outside. Alternatively, if any one of the anti-connection part and the dam is cracked, there may occur a problem in that the second encapsulation layer flows over the optical area and the through-hole in the optical area.

With reference to FIGS. 5 and 6 together, the plurality of anti-connection parts CP may be disposed between the dam DAM and the through-hole TH. The plurality of anti-connection part CP may be formed to suppress the permeation of moisture or oxygen by disconnecting the light-emitting layer EL. For example, the plurality of anti-connection parts CP may be disposed to protect the light-emitting element ED in the display area AA from moisture to oxygen that may be introduced from the through-hole TH. The light-emitting layer EL of the light-emitting element ED may be deposited on a front surface of the display panel PN and may also be uniformly deposited in the optical area OA. Because of the nature of the organic material, the light-emitting layer EL has high reactivity and dispersity in respect to moisture and oxygen, such that moisture and oxygen may be transmitted to the light-emitting element ED in the display area AA. The plurality of anti-connection parts CP may partially disconnect the light-emitting layer EL to suppress this problem.

In addition, the plurality of anti-connection parts CP may be further disposed between the dam DAM and the display area AA. Hereinafter, for convenience of description, the plurality of anti-connection parts CP disposed between the dam DAM and the through-hole TH will be referred to as first anti-connection parts 140, and the plurality of anti-connection parts CP disposed between the dam DAM and the display area AA will be referred to as second anti-connection parts 150.

The first anti-connection part 140 may include a first structure 141, a second structure 142, and a third structure 143. The first structure 141, the second structure 142, and the third structure 143 may each be formed as a two-layer structure including a first layer L1 and a second layer L2 disposed on the first layer L1 to disconnect the light-emitting layer EL in the optical area OA. For example, an undercut structure may be formed on a side surface of the second layer L2. Specifically, because the first layer L1 and the second layer L2 of each of the first structure 141, the second structure 142, and the third structure 143 are disposed to have a tapered shape, a difference in width may occur on an interface between the first layer L1 and the second layer L2. Because a top surface of the first layer L1 may be formed to be narrower than a bottom surface of the second layer L2, an undercut structure in which a part of the bottom surface of the second layer L2 is exposed may be formed. Therefore, the light-emitting layer EL deposited on the front surface of the display panel PN may be disconnected by the undercut structures of the side surfaces of the second layers L2 of the first structure 141, the second structure 142, and the third structure 143. However, the shapes of the first structure 141, the second structure 142, and the third structure 143 are not limited thereto and may be implemented as various shapes that may form the undercut structures.

The first structure 141, the second structure 142, and the third structure 143, which constitute the first anti-connection part 140, may be made of an organic material and an inorganic material. For example, an upper portion of each of the first structure 141, the second structure 142, and the third structure 143 may be made of the same material as the second planarization layer 115b. However, the present specification is not limited thereto. In addition, a lower portion of each of the first structure 141, the second structure 142, and the third structure 143 may be made of the same material as the second interlayer insulation layer 113b. However, the present specification is not limited thereto.

The second anti-connection part 150 may include a fourth structure 151 and a fifth structure 152. Like the first structure 141, the second structure 142, and the third structure 143, the fourth structure 151 and the fifth structure 152, which constitute the second anti-connection part 150, may each have a two-layer structure including the first layer L1 and the second layer L2 on the first layer L1. The second encapsulation layer 117b disposed on the second anti-connection part 150 makes it difficult for moisture to oxygen to permeate into an upper portion of the second anti-connection part 150. Therefore, the undercut structure may be formed on the side surface of the second layer L2 of the second anti-connection part 150 in order to inhibit moisture and oxygen from permeating into the lateral portion on which the through-hole TH or the first anti-connection part 140 is disposed. The arrangement of the first anti-connection part 140 and the second anti-connection part 150 may inhibit moisture and oxygen from permeating into the light-emitting element ED in the display area AA from the optical area OA through the light-emitting layer EL.

The fourth structure 151 and the fifth structure 152, which constitute the second anti-connection part 150, may also be made of an organic material and an inorganic material. For example, the first layer L1 of each of the fourth structure 151 and the fifth structure 152 may be made of the same material as the second interlayer insulation layer 113b, and the second layer L2 of each of the fourth structure 151 and the fifth structure 152 may be made of the same material as the second planarization layer 115b. However, the present specification is not limited thereto.

In case that the plurality of anti-connection parts is disposed in the optical area to suppress the permeation of moisture or oxygen from the through-hole as described above, a level difference occurs on upper portions of the plurality of anti-connection parts because of the shapes of the plurality of anti-connection parts. There is a problem in that this level difference causes refraction on the polarizing layer positioned above the plurality of anti-connection parts. The refraction occurring on the polarizing layer causes a problem in that the polarizing layer is visually recognized by the user. In addition, when the refraction occurs on the polarizing layer, light blurring occurs in the area in which the refraction occurs, which causes a problem in that the image quality of the display device deteriorates.

Therefore, in the display device 100 according to the embodiment of the present specification, the metal pattern 125 is disposed between the first anti-connection parts 140 on the first anti-connection part 140. Therefore, the occurrence of refraction on the polarizing layer 130 disposed above the first anti-connection part 140 may be suppressed by suppressing the level difference on the upper portion of the first anti-connection part 140.

With reference to FIG. 6, a plurality of inorganic insulation layers may be disposed along the shape of the first anti-connection part 140 on the first anti-connection part 140 in the optical area OA (for instance, the plurality of inorganic insulation layers may conform to a surface profile of the first anti-connection part 140). For example, the plurality of inorganic insulation layers may be the first inorganic encapsulation layer 117a, the second inorganic encapsulation layer 117c, the touch buffer layer 118a, and the touch interlayer insulation layer 118b.

A height of each of the plurality of inorganic insulation layers disposed between the plurality of first anti-connection parts 140 is different from a height of a portion that overlaps the plurality of first anti-connection parts 140. In particular, on the touch interlayer insulation layer 118b positioned at the uppermost end of the plurality of inorganic insulation layers, a level difference occurs between the plurality of first anti-connection parts 140 because of the above-mentioned height difference. For example, the plurality of inorganic insulation layers may have shapes including a plurality of convex portions CV in which a distance between the cathode E2 and the touch interlayer insulation layer 118b, which is the uppermost end of the plurality of inorganic insulation layers, is relatively short, and a plurality of concave portions CC in which a distance between the touch interlayer insulation layer 118b and the cathode E2 is relatively long. For example, the plurality of inorganic insulation layers may have shapes including the plurality of convex portions CV configured to overlap the first anti-connection parts 140, and the plurality of concave portions CC positioned between the first anti-connection parts 140.

According to the embodiment of the present specification, the metal pattern 125 may be configured as a plurality of metal patterns 125 spaced apart from the plurality of concave portions CC of the plurality of inorganic insulation layers. For example, a top surface of the metal pattern 125 may be disposed on the same plane as top surfaces of the plurality of convex portions CV.

The metal pattern 125 may be disposed on the same layer and made of the same material as the plurality of touch electrodes 122. For example, the metal pattern 125 may be configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. However, the present specification is not limited thereto. For example, the metal pattern 125 may each have a three-layer structure made of titanium (Ti), aluminum (Al), and titanium (Ti). In the display device 100 according to the embodiment of the present specification, the metal pattern 125 is disposed on the same layer and made of the same material as the plurality of touch electrodes 122, such that the metal pattern 125 may planarize the uppermost portions of the plurality of inorganic insulation layers.

According to the embodiment of the present specification, the metal pattern 125 is disposed on the concave portion CC of the touch interlayer insulation layer 118b that is the uppermost end of the plurality of inorganic insulation layers disposed above the first anti-connection part 140. For example, the metal pattern 125 may be formed on the touch interlayer insulation layer 118b disposed in the optical area OA by a process identical to the process of forming the plurality of touch electrodes 122 on the touch interlayer insulation layer 118b in the display area AA. For example, the plurality of touch electrodes 122 and the plurality of metal patterns 125 may be formed by depositing the metal layer in the display area AA and the optical area OA and then patterning the metal layer. However, the present specification is not limited thereto. In this case, a top surface of the metal pattern 125 may be positioned on the same plane as the convex portion CV of the plurality of inorganic insulation layers.

Therefore, the plurality of inorganic insulation layers on the first anti-connection part 140 may be planarized, and the polarizing layer 130 disposed above the plurality of inorganic insulation layers may also be disposed flat. Therefore, the visibility of the display device 100 according to the embodiment of the present specification may be improved, light blurring in the optical area OA may be suppressed, and the image quality of the display device 100 may be improved.

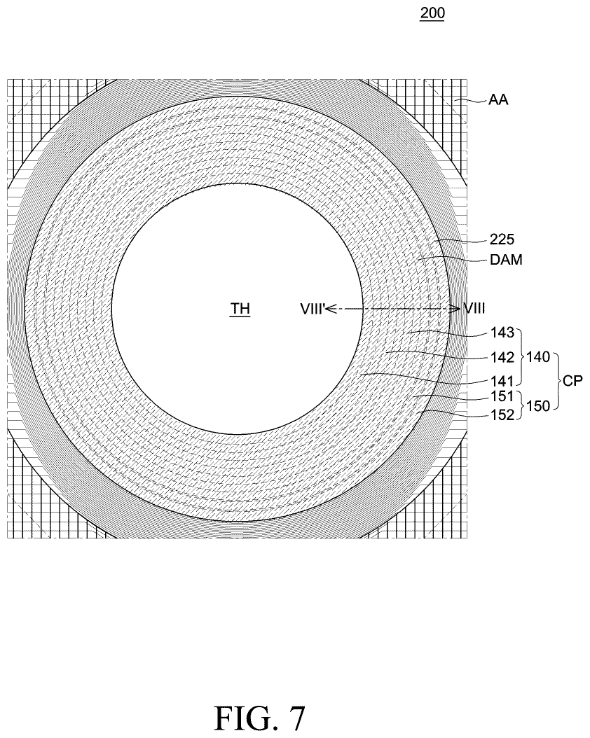

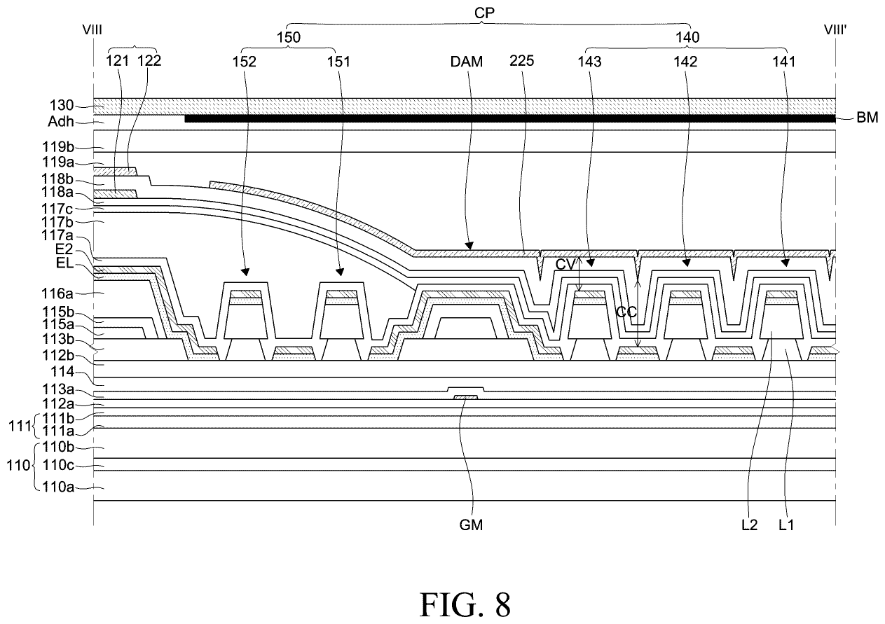

FIG. 7 is a top plan view of a display device according to another embodiment of the present specification. FIG. 8 is a cross-sectional view taken along line VIII-VIII′ in FIG. 7. FIGS. 7 and 8 are substantially identical in configuration to FIGS. 1 to 6, except for a metal pattern 225. Therefore, for convenience of description, a repeated description will be omitted, except for the metal pattern 225.

In a display device 200 according to another embodiment of the present specification, the metal pattern 225 is disposed on the first anti-connection part 140 and covers an upper portion of the first anti-connection part 140. Therefore, the occurrence of refraction on the polarizing layer 130 disposed above the first anti-connection part 140 may be suppressed by reducing the level difference on the upper portion of the first anti-connection part 140.

With reference to FIGS. 7 and 8 in the present application, the plurality of inorganic insulation layers may be disposed along the shape of the first anti-connection part 140 on the first anti-connection part 140 in the optical area OA (for instance, the plurality of inorganic insulation layers may conform to a surface profile of the first anti-connection part 140). For example, the inorganic insulation layers may be the first inorganic encapsulation layer 117a, the second inorganic encapsulation layer 117c, the touch buffer layer 118a, and the touch interlayer insulation layer 118b.

The plurality of inorganic insulation layers may have shapes including the plurality of convex portions CV configured to overlap the first anti-connection parts 140, and the plurality of concave portions CC positioned between the first anti-connection parts 140.

In the display device 200 according to another embodiment of the present specification, the metal pattern 225 may be disposed to cover all the plurality of concave portions CC and the plurality of convex portions CV. For example, the metal pattern 225 may be disposed along the shapes of the plurality of inorganic insulation layers. In other words, the metal pattern 225 conforms to and overlays the surface profile of the plurality of inorganic insulation layers. In addition, FIGS. 7 and 8 in the present application illustrate that the metal pattern 225 covers all the plurality of inorganic insulation layers disposed above the first anti-connection part 140, the second anti-connection part 150, and the dam DAM. However, the present specification is not limited thereto. For example, the metal pattern 225 may be disposed to cover only the plurality of inorganic insulation layers disposed above the dam DAM and the first anti-connection part 140.

For example, the metal pattern 225 may be disposed on the same layer and made of the same material as the plurality of touch electrodes 122. For example, the metal pattern 125 may be configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. However, the present specification is not limited thereto. For example, the metal pattern 225 may each have a three-layer structure made of titanium (Ti), aluminum (Al), and titanium (Ti).

In the display device 200 according to another embodiment of the present specification, the metal pattern 225 may be disposed to cover the convex portion CV and the concave portion CC on the touch interlayer insulation layer 118b that is the uppermost end of the plurality of inorganic insulation layers disposed above the first anti-connection part 140. For example, the metal pattern 225 may be formed on the touch interlayer insulation layer 118b in the optical area OA by a process identical to the process of forming the plurality of touch electrodes 122 on the touch interlayer insulation layer 118b in the display area AA. For example, the plurality of touch electrodes 122 and the plurality of metal patterns 225 may be formed by depositing the metal layer in the display area AA and the optical area OA and then patterning the metal layer. However, the present specification is not limited thereto. For example, the metal pattern 225 may be formed in the form of one layer by patterning. Therefore, the metal pattern 225 may cover not only the upper portion of the first anti-connection part 140 but also the upper portions of the dam DAM and the second anti-connection part 150. In addition, the metal pattern 225 may be disposed to overlap a black matrix BM provided above the metal pattern 225. Therefore, even though the metal pattern 225 is formed to cover the first anti-connection part 140, the second anti-connection part 150, and the dam DAM, the black matrix BM may inhibit the metal pattern 225 from being visually recognized by the user in the optical area OA. For example, the metal pattern 225 may be disposed to overlap the black matrix BM and disposed so as not to further protrude in the direction of the display area AA than the black matrix BM.

In the display device 200 according to another embodiment of the present specification, the metal pattern 225 may be shaped to connect the metal pattern 225, which is disposed on the concave portion CC, to the metal pattern 225 disposed on the convex portion CV. Because of a level difference between the plurality of inorganic insulation layers of the metal pattern 225, a fine level difference may occur between the metal pattern 225 disposed on the concave portion CC and the metal pattern 225 disposed on the convex portion CV. However, because the level difference of the metal pattern 225 is much smaller than the level difference of the plurality of inorganic insulation layers, the metal pattern 225 may compensate for the level difference caused by the first anti-connection parts 140 between the adjacent first anti-connection parts 140. Therefore, the metal pattern 225 may reduce the level difference of the upper portion of the first anti-connection part 140. Therefore, it is possible to reduce the refraction on the plurality of inorganic insulation layers on the first anti-connection part 140 and reduce the refraction on the polarizing layer 130 disposed above the plurality of inorganic insulation layers. Therefore, the visibility of the display device 200 according to another embodiment of the present specification may be improved, light blurring in the optical area OA may be suppressed, and the image quality of the display device 200 may be improved.

In the display device 200 according to another embodiment of the present specification, a process of planarizing the first organic layer 119a on the first anti-connection part 140 may be additionally performed to completely remove the level difference of the upper portion of the first anti-connection part 140. For example, a material for forming the first organic layer 119a is applied onto the first anti-connection part 140 having the upper portion on which the plurality of inorganic insulation layers is formed. Thereafter, a slit mask including opening portions is positioned to correspond to an area that overlaps the first anti-connection part 140. Thereafter, exposure, development, and heat treatment processes are performed. Therefore, the area, which overlaps the first anti-connection part 140, is irradiated with a larger amount of light than the area that does not overlap the first anti-connection part 140. Therefore, a thickness of the first organic layer 119a, which is disposed above the area that overlaps the first anti-connection part 140, may be smaller than a thickness of the first organic layer 119a disposed above the area that does not overlap the first anti-connection part 140. Therefore, even though a bottom surface of the first organic layer 119a has a level difference, a top surface of the first organic layer 119a may be formed flat. Therefore, the second organic layer 119b and the polarizing layer 130 disposed on the first organic layer 119a may also be disposed flat. Therefore, the visibility of the display device 200 according to another embodiment of the present specification may be improved, light blurring in the optical area OA may be suppressed, and the image quality of the display device 200 may be improved. In addition, in the display device 200 according to another embodiment of the present specification, the metal pattern 225 is disposed above the first anti-connection part 140, and the level difference caused by the first anti-connection part 140 is compensated, such that the exposure dose and exposure time may be reduced, the process time and costs may be reduced, and the process may be optimized.

The exemplary embodiments of the present disclosure can also be described as follows:

According to an aspect of the present disclosure, a display device comprising a substrate comprising a display area, an optical area surrounded by the display area and comprising a through-hole, and a non-display area configured to surround the display area, a dam disposed in the optical area on the substrate and configured to surround the through-hole, a plurality of anti-connection parts disposed in the optical area on the substrate and disposed to be closer to the through-hole than the dam, and a metal pattern disposed on the plurality of anti-connection parts and disposed between the plurality of anti-connection parts.

The display device may further include a plurality of light-emitting elements disposed in the display area and each comprising an anode, a light-emitting layer, and a cathode, the plurality of anti-connection parts each comprise a first layer and a second layer disposed on the first layer, the first layer and the second layer each have a tapered shape, a top surface of the first layer is narrower than a bottom surface of the second layer, and the light-emitting layer and the cathode may extend to the optical area and may be separated in the optical area by the plurality of anti-connection parts.

The display device may further include a plurality of inorganic insulation layers disposed on the plurality of anti-connection parts, the plurality of inorganic insulation layers is disposed along shapes of the plurality of anti-connection parts, the plurality of inorganic insulation layers has shapes comprising a plurality of convex portions configured to overlap the plurality of anti-connection parts, and a plurality of concave portions positioned between the plurality of anti-connection parts, and the metal pattern may be configured as a plurality of metal patterns disposed on the plurality of concave portions and spaced apart from one another.

A top surface of the metal pattern may be disposed on the same plane as top surfaces of the plurality of convex portions.

The display device may further include a plurality of inorganic insulation layers disposed on the plurality of anti-connection parts, the plurality of inorganic insulation layers is disposed along shapes of the plurality of anti-connection parts, the plurality of inorganic insulation layers has shapes comprising a plurality of convex portions configured to overlap the plurality of anti-connection parts, and a plurality of concave portions positioned between the plurality of anti-connection parts, and the metal pattern may be disposed to cover all the plurality of concave portions and the plurality of convex portions.

The metal pattern may be disposed along shapes of the plurality of inorganic insulation layers.

The metal pattern may be shaped to connect the metal pattern, which is disposed on the plurality of concave portions of the plurality of inorganic insulation layers, to the metal pattern disposed on the convex portions of the plurality of inorganic insulation layers.

The metal pattern may be disposed to extend to an upper portion of the dam.

The display device may further include an encapsulation part disposed on the plurality of light-emitting elements and comprising a first inorganic encapsulation layer, an organic encapsulation layer on the first inorganic encapsulation layer, and a second inorganic encapsulation layer on the organic encapsulation layer; and a touch sensing part disposed on the encapsulation part, the touch sensing part comprises a touch buffer layer disposed on the encapsulation part, a plurality of touch connection electrodes disposed on the touch buffer layer, a touch interlayer insulation layer disposed on the plurality of touch connection electrodes, and a plurality of touch electrodes disposed on the touch interlayer insulation layer, and the plurality of inorganic insulation layers may be the first inorganic encapsulation layer, the second inorganic encapsulation layer, the touch buffer layer, and the touch interlayer insulation layer.

The metal pattern may be made of the same material as the plurality of touch electrodes.

The display device may further include a black matrix disposed on the touch sensing part in the optical area, the metal pattern may be disposed in an area that overlaps the black matrix.

The display device may further include an optical electronic device disposed to overlap the optical area.

According to another aspect of the present disclosure, a display device comprising a substrate comprising a display area, an optical area surrounded by the display area and comprising a through-hole, and a non-display area configured to surround the display area, a plurality of light-emitting elements disposed in the display area on the substrate and each comprising an anode, a light-emitting layer, and a cathode, an encapsulation part disposed on the plurality of light-emitting elements and comprising a first inorganic encapsulation layer, an organic encapsulation layer disposed on the first inorganic encapsulation layer, and a second inorganic encapsulation layer disposed on the organic encapsulation layer, a touch sensing part disposed on the encapsulation part and comprising a touch buffer layer, a plurality of touch connection electrodes disposed on the touch buffer layer, a touch interlayer insulation layer disposed on the plurality of touch connection electrodes, and a plurality of touch electrodes disposed on the touch interlayer insulation layer, a dam configured to surround the through-hole in the optical area on the substrate and define a concentric circle together with the through-hole, a plurality of anti-connection parts disposed to be closer to the through-hole than the dam in the optical area on the substrate and configured to define a concentric circle together with the through-hole, and a metal pattern disposed on the plurality of anti-connection parts, disposed between the plurality of anti-connection parts, and configured to define a concentric circle together with the through-hole.

The metal pattern may be made of the same material as the plurality of touch electrodes.

The display device may further include a plurality of inorganic insulation layers extending to the optical area from the display area and disposed on the plurality of anti-connection parts, the plurality of inorganic insulation layers comprises the first inorganic encapsulation layer, the second inorganic encapsulation layer, the touch buffer layer, and the touch interlayer insulation layer, the plurality of inorganic insulation layers is disposed along shapes of the plurality of anti-connection parts, and the plurality of inorganic insulation layers may have shapes comprising a plurality of convex portions configured to overlap the plurality of anti-connection parts, and a plurality of concave portions positioned between the plurality of anti-connection parts.

The metal pattern may be configured as a plurality of metal patterns disposed on the plurality of concave portions and spaced apart from one another.

A top surface of the metal pattern may be disposed on the same plane as top surfaces of the plurality of convex portions.

The metal pattern may be disposed to cover all the plurality of concave portions and the plurality of convex portions.

The various embodiments disclosed herein resolve the two problems that a through-hole introduces in an OLED touch display, namely optical unevenness and a direct moisture path, by combining three coordinated structures. First, tapered two layer anti connection walls encircle the hole and deliberately interrupt the cathode and emissive stack so that any water or oxygen entering the aperture cannot migrate laterally into active pixels. Second, a metal pattern deposited in the same step as the touch electrodes is lithographically shaped either as discrete islands or as a continuous sheet that fills the valleys between the walls, bringing the top surface flush with the surrounding terrain and eliminating light bleed. Third, the dam, the anti connection parts and the metal pattern are arranged as concentric rings, so each ring backs up the others for both barrier and planarization functions while still leaving routing space around the aperture.

Because the planar metal sits beneath an existing black matrix stripe, it is hidden from view, yet its presence allows a thinner organic planarization film and therefore shorter photolithography exposure times, cutting cost without extra masks. The resulting full screen OLED can host an under display camera or sensor that looks visually seamless, resists environmental ingress and is manufacturable on standard touch OLED process flows.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate comprising a display area, an optical area surrounded by the display area and comprising a through-hole, and a non-display area configured to surround the display area;
a dam disposed in the optical area on the substrate and configured to surround the through-hole;
a plurality of anti-connection parts disposed in the optical area on the substrate and disposed to be closer to the through-hole than the dam; and
a metal pattern disposed on the plurality of anti-connection parts and disposed between the plurality of anti-connection parts.

2. The display device of claim 1, further comprising:
a plurality of light-emitting elements disposed in the display area and each comprising an anode, a light-emitting layer, and a cathode,
wherein the plurality of anti-connection parts each comprise a first layer and a second layer disposed on the first layer,
wherein the first layer and the second layer each have a tapered shape,
wherein a top surface of the first layer is narrower than a bottom surface of the second layer, and
wherein the light-emitting layer and the cathode extend to the optical area and are separated in the optical area by the plurality of anti-connection parts.

3. The display device of claim 1, further comprising:
a plurality of inorganic insulation layers disposed on the plurality of anti-connection parts,
wherein the plurality of inorganic insulation layers conforms to a surface profile of the plurality of anti-connection parts,
wherein the plurality of inorganic insulation layers has shapes comprising a plurality of convex portions configured to overlap the plurality of anti-connection parts, and a plurality of concave portions positioned between the plurality of anti-connection parts, and
wherein the metal pattern is configured as a plurality of metal patterns disposed on the plurality of concave portions and spaced apart from one another.

4. The display device of claim 3, wherein a top surface of the metal pattern is disposed on the same plane as top surfaces of the plurality of convex portions.

5. The display device of claim 1, further comprising:
a plurality of inorganic insulation layers disposed on the plurality of anti-connection parts,
wherein the plurality of inorganic insulation layers conforms to a surface profile of the plurality of anti-connection parts,
wherein the plurality of inorganic insulation layers has shapes comprising a plurality of convex portions configured to overlap the plurality of anti-connection parts, and a plurality of concave portions positioned between the plurality of anti-connection parts, and
wherein the metal pattern is disposed to cover all the plurality of concave portions and the plurality of convex portions.

6. The display device of claim 5, wherein the metal pattern conforms to a surface profile of the plurality of inorganic insulation layers.

7. The display device of claim 6, wherein the metal pattern is shaped to connect the metal pattern, which is disposed on the plurality of concave portions of the plurality of inorganic insulation layers, to the metal pattern disposed on the convex portions of the plurality of inorganic insulation layers.

8. The display device of claim 6, wherein the metal pattern is disposed to extend to an upper portion of the dam.

9. The display device of claim 4, further comprising:
an encapsulation part disposed on the plurality of light-emitting elements and comprising a first inorganic encapsulation layer, an organic encapsulation layer on the first inorganic encapsulation layer, and a second inorganic encapsulation layer on the organic encapsulation layer; and
a touch sensing part disposed on the encapsulation part,
wherein the touch sensing part comprises:
a touch buffer layer disposed on the encapsulation part;
a plurality of touch connection electrodes disposed on the touch buffer layer;
a touch interlayer insulation layer disposed on the plurality of touch connection electrodes; and
a plurality of touch electrodes disposed on the touch interlayer insulation layer, and
wherein the plurality of inorganic insulation layers is the first inorganic encapsulation layer, the second inorganic encapsulation layer, the touch buffer layer, and the touch interlayer insulation layer.

10. The display device of claim 9, wherein the metal pattern is made of the same material as the plurality of touch electrodes.

11. The display device of claim 9, further comprising:
a black matrix disposed on the touch sensing part in the optical area,
wherein the metal pattern is disposed in an area that overlaps the black matrix.

12. The display device of claim 1, further comprising:
an optical electronic device disposed to overlap the optical area.

13. A display device comprising:
a substrate comprising a display area, an optical area surrounded by the display area and comprising a through-hole, and a non-display area configured to surround the display area;
a plurality of light-emitting elements disposed in the display area on the substrate and each comprising an anode, a light-emitting layer, and a cathode;
an encapsulation part disposed on the plurality of light-emitting elements and comprising a first inorganic encapsulation layer, an organic encapsulation layer disposed on the first inorganic encapsulation layer, and a second inorganic encapsulation layer disposed on the organic encapsulation layer;
a touch sensing part disposed on the encapsulation part and comprising a touch buffer layer, a plurality of touch connection electrodes disposed on the touch buffer layer, a touch interlayer insulation layer disposed on the plurality of touch connection electrodes, and a plurality of touch electrodes disposed on the touch interlayer insulation layer;
a dam configured to surround the through-hole in the optical area on the substrate and surrounding the through-hole in a circular arrangement concentric with the through-hole;
a plurality of anti-connection parts disposed to be closer to the through-hole than the dam in the optical area on the substrate, and arranged in a circular arrangement concentric with the through-hole; and
a metal pattern disposed on the plurality of anti-connection parts, disposed between the plurality of anti-connection parts, and arranged in a circular arrangement concentric with the through-hole.

14. The display device of claim 13, wherein the metal pattern is made of the same material as the plurality of touch electrodes.

15. The display device of claim 14, further comprising:
a plurality of inorganic insulation layers extending to the optical area from the display area and disposed on the plurality of anti-connection parts,
wherein the plurality of inorganic insulation layers comprises the first inorganic encapsulation layer, the second inorganic encapsulation layer, the touch buffer layer, and the touch interlayer insulation layer,
wherein the plurality of inorganic insulation layers conforms to a surface profile of the plurality of anti-connection parts, and
wherein the plurality of inorganic insulation layers has shapes comprising a plurality of convex portions configured to overlap the plurality of anti-connection parts, and a plurality of concave portions positioned between the plurality of anti-connection parts.

16. The display device of claim 15, wherein the metal pattern is configured as a plurality of metal patterns disposed on the plurality of concave portions and spaced apart from one another.

17. The display device of claim 16, wherein a top surface of the metal pattern is disposed on the same plane as top surfaces of the plurality of convex portions.

18. The display device of claim 16, wherein the metal pattern is disposed to cover all the plurality of concave portions and the plurality of convex portions.
